(19) United States
(12) Patent Application Publication
(10) Pub. No.: US 2010/0134137 A1
(43) Pub. Date: Jun. 3, 2010

(54) LIQUID CRYSTAL DISPLAY PANEL AND ITS INSPECTING METHOD

(76) Inventor: Kazutoshi Kida, Osaka (JP)

Correspondence Address: BIRCH STEWART KOLASCH & BIRCH, PO BOX 747, FALLS CHURCH, VA, 22040-0747, US

(21) Appl. No.: 12/597,444

(22) PCT Filed: Dec. 13, 2007
(86) PCT No.: PCT/JP2007/074013

§ 371 Date: Oct. 23, 2009

(30) Foreign Application Priority Data
Apr. 25, 2007 (JP) 2007-115016

(51) Int. Cl. G01R 31/02; G02F 1/1343

(52) U.S. Cl. 324/770; 349/149

(57) ABSTRACT

It is an object to provide a liquid crystal display panel that is configured to surely detect a crack or a defect that may result in a big break later with high possibility, so that the output of a poor product can be prevented or the reduction of manufacturing costs can be promoted and, at the same time, a liquid crystal display panel with high reliability can be produced. A liquid crystal display panel (1) is provided with a pixel substrate (2) comprised of a plurality of scanning lines (6) and a plurality of data lines (7) that are disposed to intersect with each other on an insulating substrate, a counter substrate (4) provided with a counter electrode on an insulating substrate and a liquid crystal layer held between the pixel substrate (2) and the counter substrate (4), wherein the pixel substrate (2) is provided with a first inspecting conductor (5a) along its outer circumference and a second inspecting conductor (5b) in the inside circumference of the first inspecting conductor (5a).

### TECHNICAL FIELD

The present invention relates to a liquid crystal display panel used in a liquid crystal display device, and further relates to an inspecting method of a liquid crystal display panel.

### BACKGROUND ART

For example, an active matrix liquid crystal display panel is formed by attaching a pixel substrate and a counter substrate to each other with a liquid crystal layer held therebetween. The pixel substrate is configured such that a plurality of scanning lines and data lines are laid on a transparent insulating substrate so as to intersect with each other, and at every intersection of a scanning line and a data line, there are formed a pixel electrode and a switching device for driving the pixel electrode. The counter substrate is configured such that a counter electrode is formed on a transparent insulating substrate.

For improved manufacturing efficiency, this type of liquid crystal display panel is generally manufactured in the following method; that is, after a plurality of pixel substrates are formed on an insulating substrate and counter substrates are each placed at a predetermined position, the insulating substrate is divided into individual pixel substrates, and then liquid crystal is sealed between each pair of pixel and counter substrates, and thus individual liquid crystal display panels are obtained.

Here, in the counter substrate, part thereof facing electrode terminals to which the scanning lines and the data lines formed on the pixel substrate are connected is separated from part thereof corresponding to a display area of the liquid crystal display panel, and the electrode terminals are exposed to the outside and electrically connected to driving ICs.

In this liquid crystal display panel manufacturing process, a method used for cutting a thus made attached substrate is to form a scribe line on a surface of the insulating substrate with a cutting member such as a wheel cutter, and subsequently apply stress to the vicinity of the scribe line to bend or tear the insulating substrate apart.

### DISCLOSURE OF THE INVENTION

### Problems to be Solved by the Invention

With this method, however, in dividing the insulating substrate, a minute crack may occur in an edge of the insulating substrate formed of glass or the like. In that case, although a minute crack hardly causes an insulating substrate to break on the moment when it occurs, when bending, pulling, or thermal stress is applied to the insulating substrate in a later process, the substrate may be broken from this crack. In particular, this occurs more frequently with an insulating substrate of a large glass. Also, in an edge of an insulating substrate, a chip may occur that is so minute that does not lead to a large break, but such a chip does not disadvantageously affect the quality of the liquid crystal display panel.

Conventionally, a crack or a chip has been optically detected and judged by visual inspection, but with this inspecting method, it is very difficult to find a minute crack. Furthermore, this method takes so much time and trouble that it inevitably increases the total cost.

In view of the above problem, an object of the present invention is to surely detect a crack in an insulating substrate of a liquid crystal display panel that is highly likely to lead to a break to prevent defective products from being shipped, to reduce production cost, and to provide a highly reliable liquid crystal display panel.

### Means for Solving the Problem

To achieve the above object, according to one aspect of the present invention, a liquid crystal display panel is provided with: A liquid crystal display panel, comprising: a pixel substrate in which a plurality of pixel electrodes and switching devices for switching the pixel electrodes are provided on an insulating substrate; a counter substrate in which a counter electrode is provided on an insulating substrate; and a liquid crystal layer held between the pixel substrate and the counter substrate. Here, a first inspecting conductor is laid along an edge of the pixel substrate, and resistance inspection is performed with respect to the first inspecting conductor by using a first inspecting pad electrically connected to each end of the first inspecting conductor to thereby detect a crack or a chip occurring in the edge of the pixel substrate.

According to this configuration, in a case in which a crack or a chip occurs in the edge of the pixel substrate, it cuts the first inspecting conductor. With this configuration, occurrence of a crack or a chip can be detected, without performing optical inspection such as visual inspection, by applying a voltage from each end of the first inspecting conductor to perform resistance inspection.

According to the present invention, in the liquid crystal display panel configured as described above, it is preferable that a second inspecting conductor be laid along an inner edge of an acceptance area provided to have a predetermined width inward from the edge of the pixel substrate, and that resistance inspection be performed with respect to the second inspecting conductor by using a second inspecting pad electrically connected to each end of the second inspecting conductor to there by detect a crack or a chip occurring in the edge of the pixel substrate.

According to this configuration, the acceptance area is provided to have the predetermined width inward from the edge of the pixel substrate as a basis for judging whether or not the size of a minute chip in the edge of the pixel substrate is acceptable, and the second inspecting conductor is laid along the inner edge of the acceptance area. Thus, a chip larger than acceptable cuts the second inspecting conductor as well as the first inspecting conductor. The first and second inspecting conductors are both cut also in a case in which a crack that may lead to a large break occurs to extend out of the acceptance area. Thus, with this configuration, by applying a voltage from each end of the second inspecting conductor to perform resistance inspection, occurrence of an unacceptably large chip or a crack can be detected, and the liquid crystal display panel can be judged as defective, without performing visual inspection.

In a case in which resistance inspection is performed with respect to both the first and second inspecting conductors, and only the first inspecting conductor is found to be cut, it cannot be judged whether the cut of the first inspecting conductor has been caused by an acceptable chip or by a crack that may lead to a large break. In such a case, by performing optical inspection to find out the cause of the cut and evaluate the liquid crystal display panel, it is possible to easily and securely pick up a defective product.

According to the present invention, in the liquid crystal display panel configured as described above, it is preferable that a third inspecting conductor be laid along an edge of the counter substrate, and that resistance inspection be performed with respect to the third inspecting conductor by using a third inspecting pad electrically connected to each end of the third inspecting conductor to thereby detect a crack or a chip occurring in the edge of the counter substrate.

According to this configuration, in a case in which a crack occurs in the edge of the counter substrate, it cuts the third inspecting conductor. With this configuration, it can be detected whether or not a crack or a chip has occurred, without performing optical inspection such as visual inspection, by applying a voltage from each end of the third inspecting conductor to perform resistance inspection.

According to the present invention, in the liquid crystal display panel configured as described above, it is preferable that the third inspecting pad be provided on the pixel substrate.

According to this configuration, since inspecting pads are collectively provided on the pixel substrate, resistance inspection can be performed with improved working efficiency.

According to the present invention, in the liquid crystal display panel structured as described above, it is preferable that a fourth inspecting conductor be laid along an inner edge of an acceptance area provided to have a predetermined width inward from the edge of the counter substrate, and that resistance inspection be performed with respect to the fourth inspecting conductor by using a fourth inspecting pad electrically connected to each end of the fourth inspecting conductor to thereby detect a crack or a chip occurring in the edge of the counter substrate.

According to this configuration, as a basis for judging whether or not the size of a minute chip occurred in the edge of the counter substrate is acceptable in terms of the quality of the liquid crystal display panel, the allowance area is provided to have the predetermined width inward from the edge of the substrate, and the fourth inspecting conductor is laid along the inner edge of the acceptance area. Thus, a chip larger than acceptable cuts the fourth inspecting conductor. The fourth inspecting conductor is cut also in a case in which a crack that may lead to a large break occurs to extend out of the acceptance area. With this configuration, by applying a voltage from each end of the fourth inspecting conductor to perform resistance inspection, occurrence of an unacceptably large chip or a break can be detected and the liquid crystal display panel can be judged as defective, without performing optical inspection such as visual inspection.

In a case in which resistance inspection is performed with respect to both the third and fourth inspecting conductors, and only the third inspecting conductor is found to be cut, it cannot be judged whether the cut of the third inspecting conductor has been caused by an acceptable chip or a crack that may lead to a large break. In such a case, by performing optical inspection to find out the cause of the cut and evaluate the liquid crystal display panel, it is possible to easily and securely pick up a defective product.

According to the present invention, in the liquid crystal display panel structured as described above, it is preferable that the fourth inspecting pad be provided on the pixel substrate.

With this configuration, since inspecting pads are collectively provided on the pixel substrate, resistance inspection can be performed with improved working efficiency.

According to the present invention, in the above-structured liquid crystal display panel obtained by dividing the insulating substrate along a division line, it is preferable that a fifth inspecting conductor be laid along an outer edge of an acceptance area provided to have a predetermined width outward from the division line in the insulating substrate of the pixel substrate, that the fifth inspecting conductor be connected to the first inspecting conductor near a division-line intersection, that a fifth inspecting pad electrically connected to each end of the fifth inspecting conductor be provided inside the division line, and that resistance inspection be performed with respect to resistance between the fifth and first inspecting conductors by using the fifth and first inspecting pads to thereby detect division performed deviating outward from the division line.

According to this configuration, in a case in which a division position is formed to deviate so much from the proper division line that it is out of the acceptance area formed outside the proper division line as a basis for judging whether or not a division position is acceptable in terms of the quality of the liquid crystal display panel, the fifth inspecting conductor laid along the outer edge of the acceptance area is not cut. On the other hand, in a case in which the insulating substrate is divided inside the acceptance area, the fifth inspecting conductor is cut. Thus, with this configuration, occurrence of unacceptable deviation can be detected, without performing visual inspection, by applying a voltage from each end of the fifth inspecting conductor to perform resistance inspection.

Furthermore, the fifth inspecting conductor is connected to the first inspecting conductor near a division-line intersection. With this configuration, in a case in which division deviation has occurred in a division line within the acceptance area, a connection portion between the fifth and first inspecting conductors near the division position is cut; in contrast, in a case in which division deviation has occurred outside the acceptance area, the connection portion between the fifth and first inspecting conductors near the division position is not cut. With this configuration, a division line with respect to which unacceptable deviation has occurred can be detected by applying a voltage between the fifth and first inspecting conductors from each end of the fifth and first inspecting pads to perform resistance inspection.

According to another aspect of the present invention, an inspecting method for inspecting the liquid crystal display panel described above includes: a resistance inspection process in which a voltage is applied to at least one of the first and second inspecting conductors; and an optical inspection process by visual inspection. Here, in the resistance inspection process, the liquid crystal display panel is evaluated in terms of defection level to judge whether or not the optical inspection process is to be performed.

According to this configuration, since resistance inspection is first performed to judge whether a liquid crystal display panel is defective or non-defective, and then optical inspection is performed only when the liquid crystal display panel cannot be evaluated by the resistance inspection alone, a defective liquid crystal display panel can be picked up efficiently.

### Advantages of the Invention

According to the present invention, it is possible to improve the efficiency of the inspecting process of liquid crystal display panels, and to pick up more securely a defective liquid crystal display panel having a chip or a crack in the edge thereof.

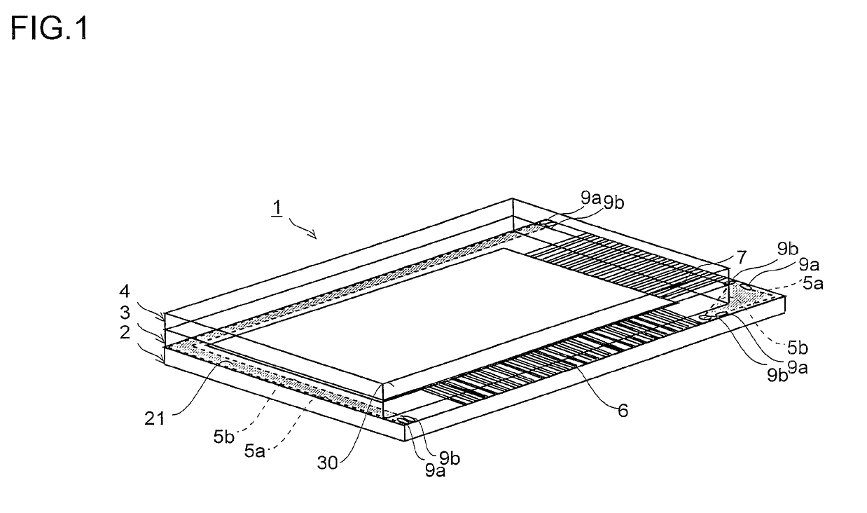

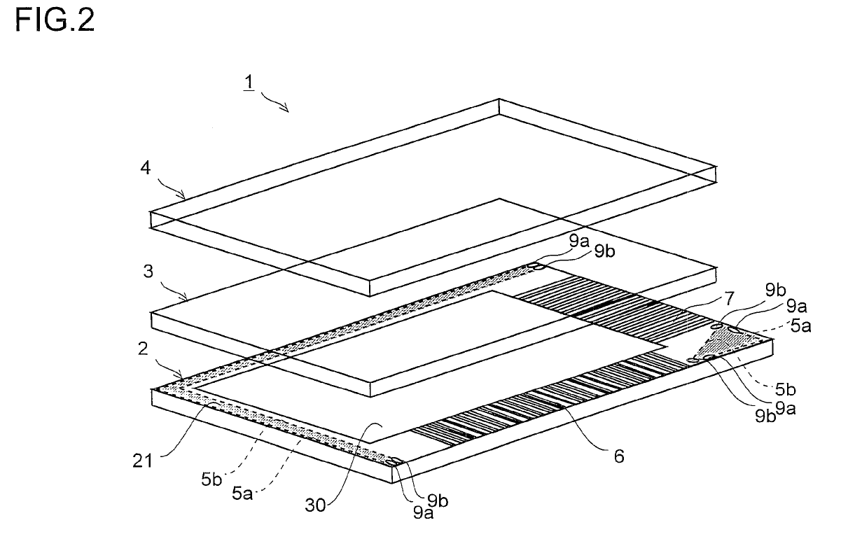

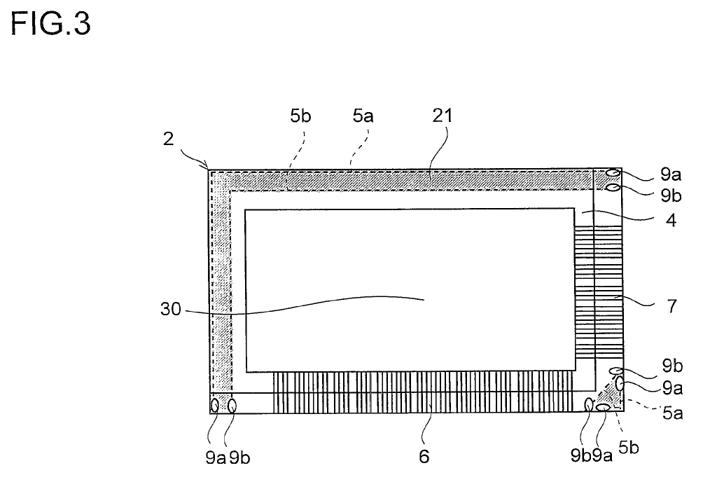

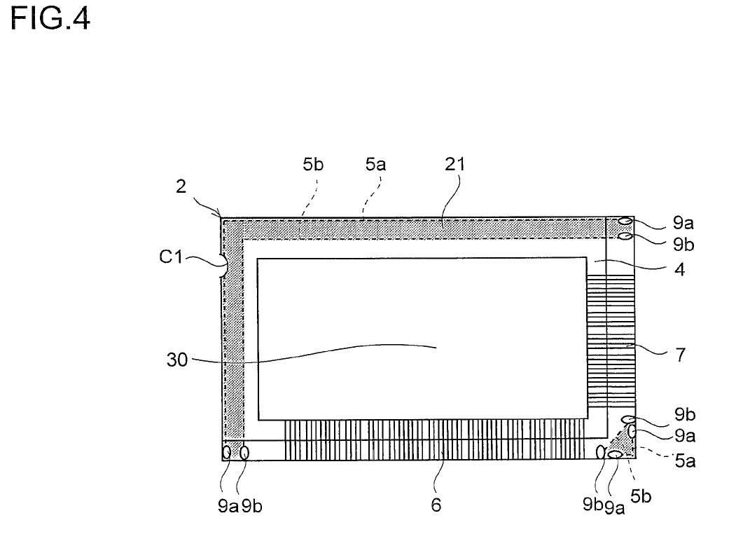

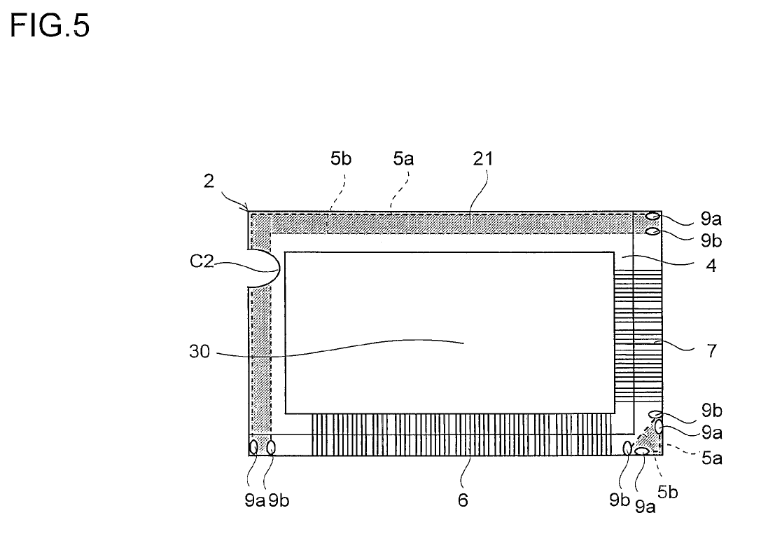

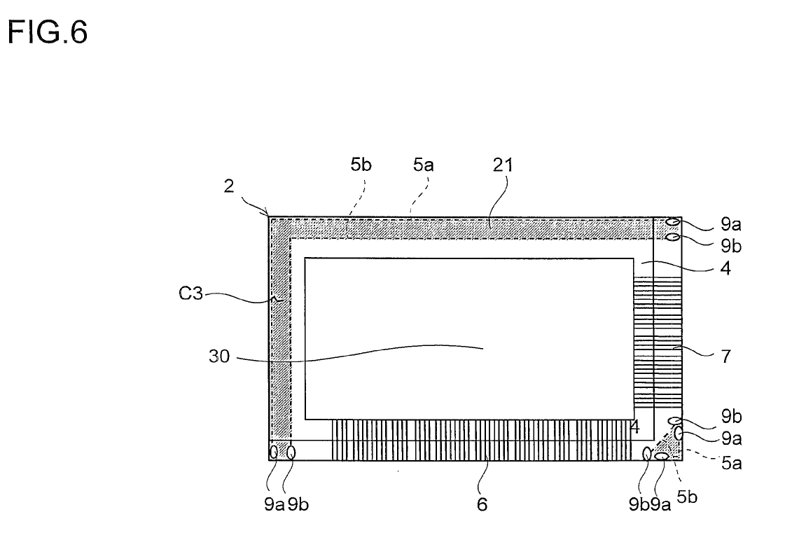

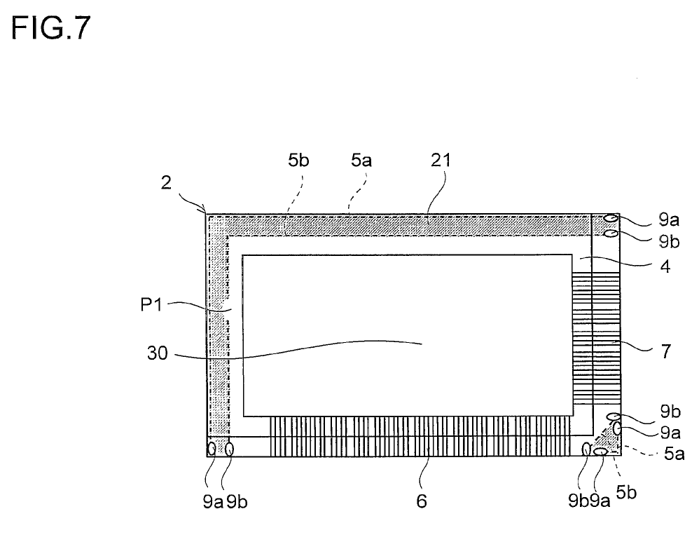

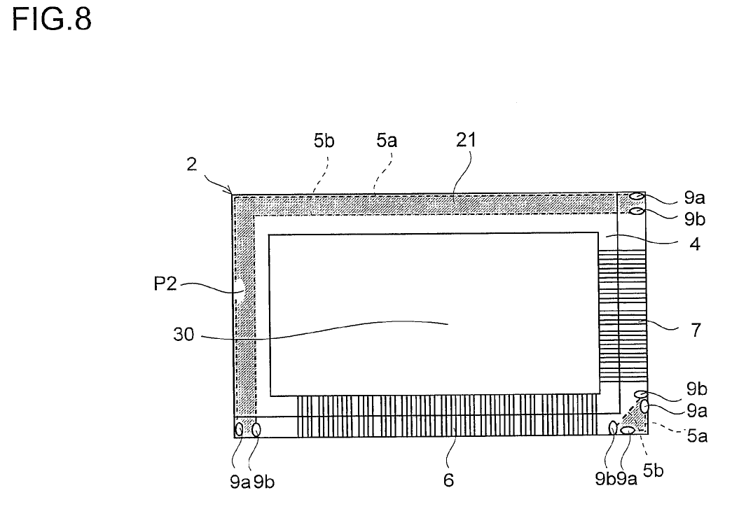

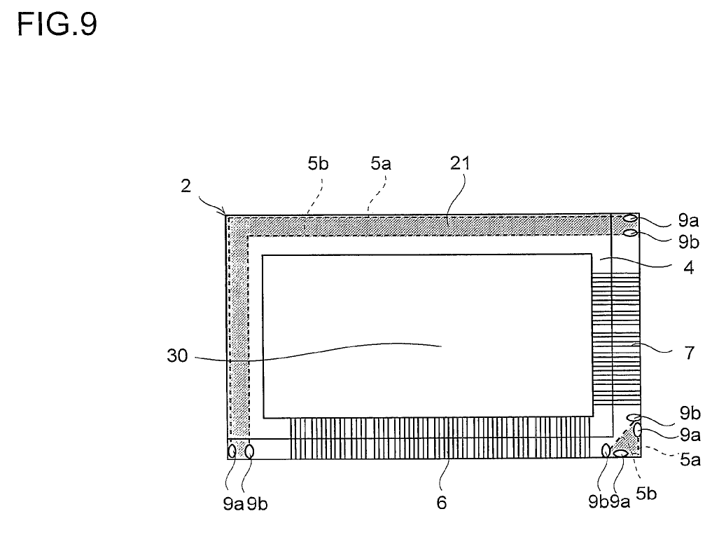

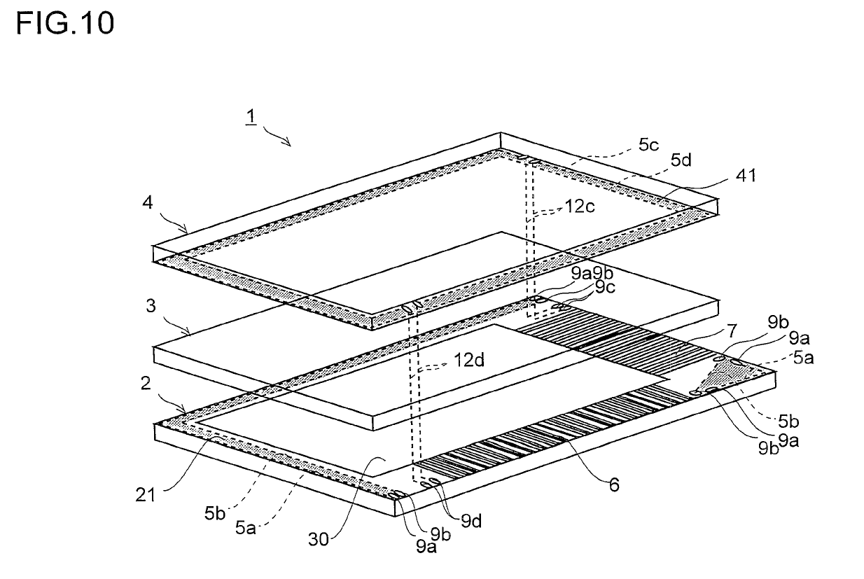

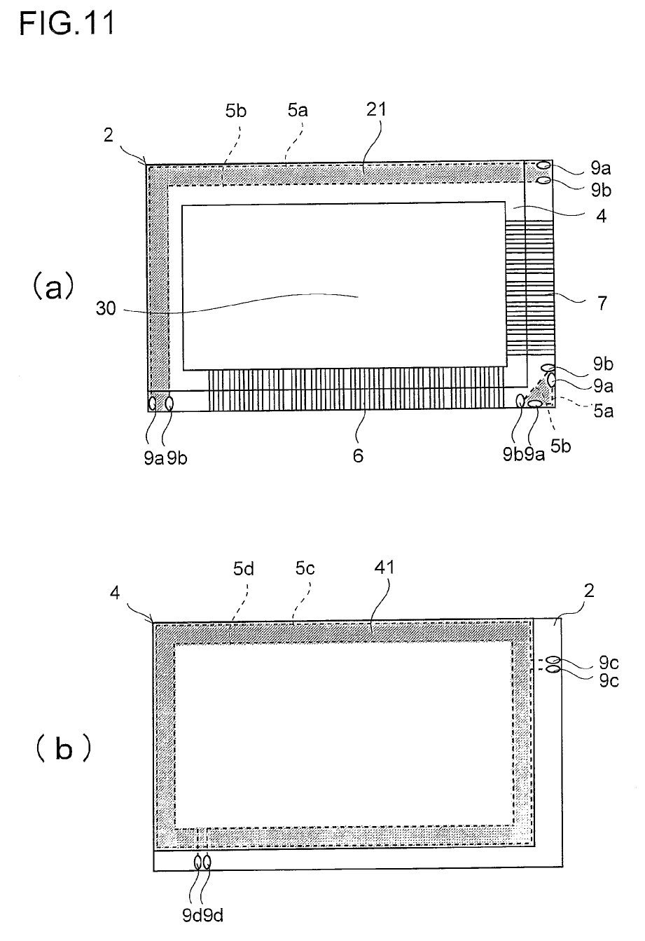

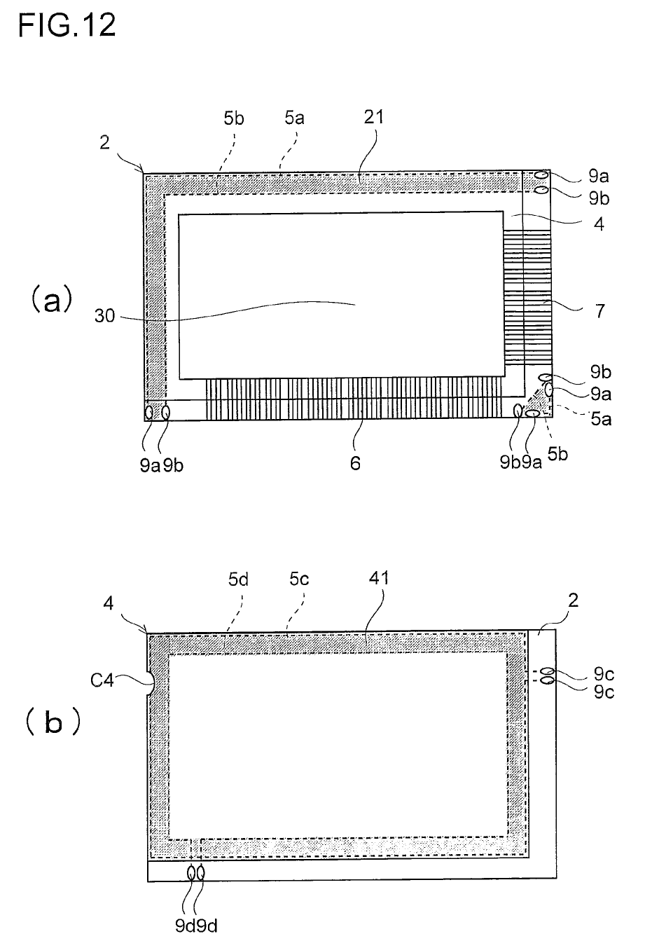

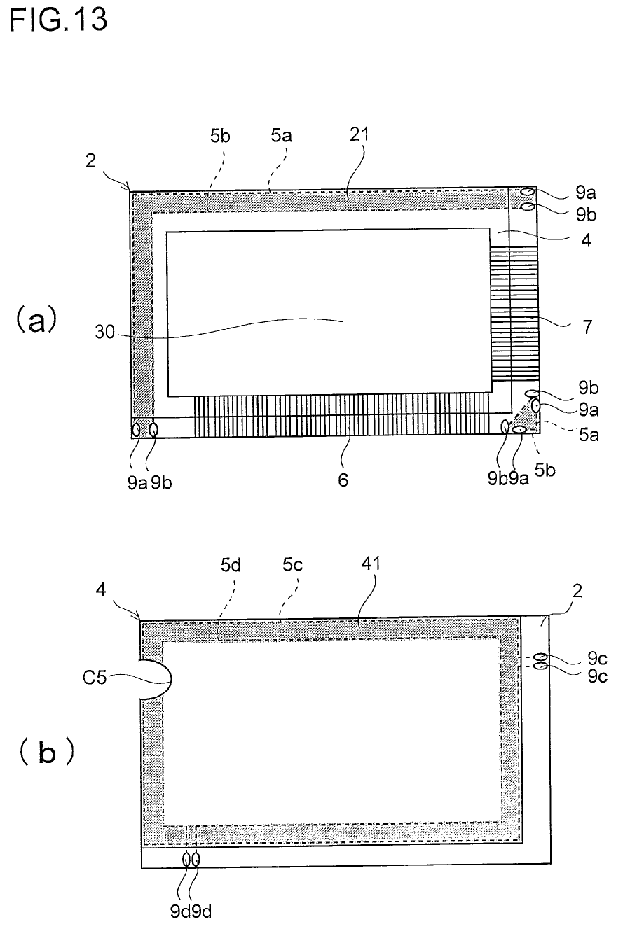

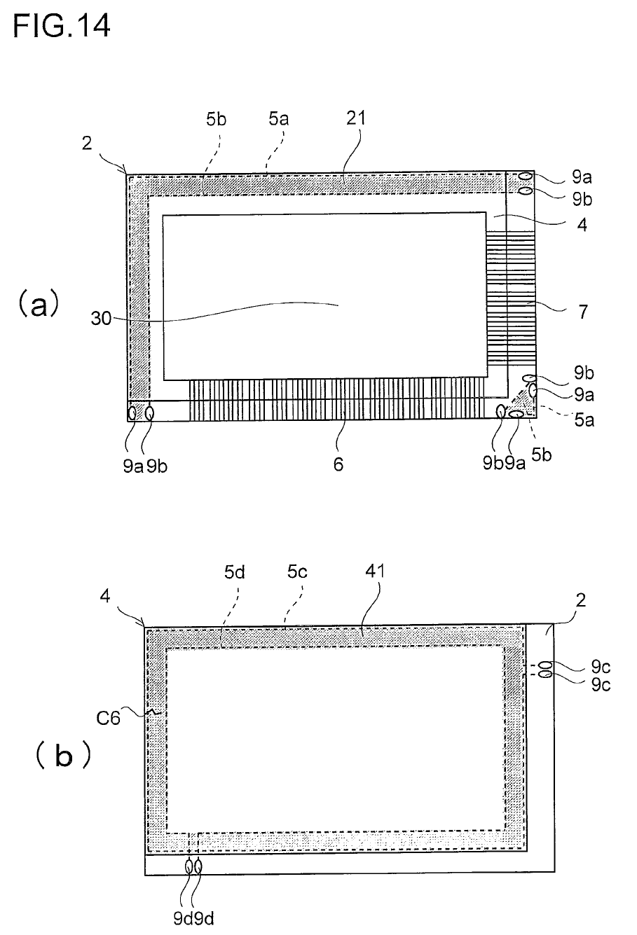

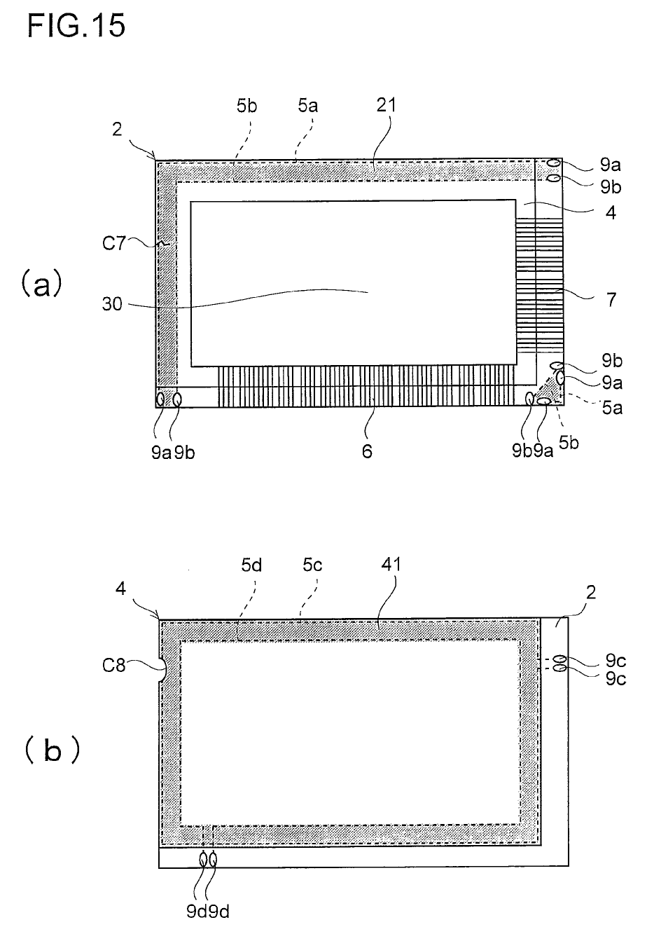

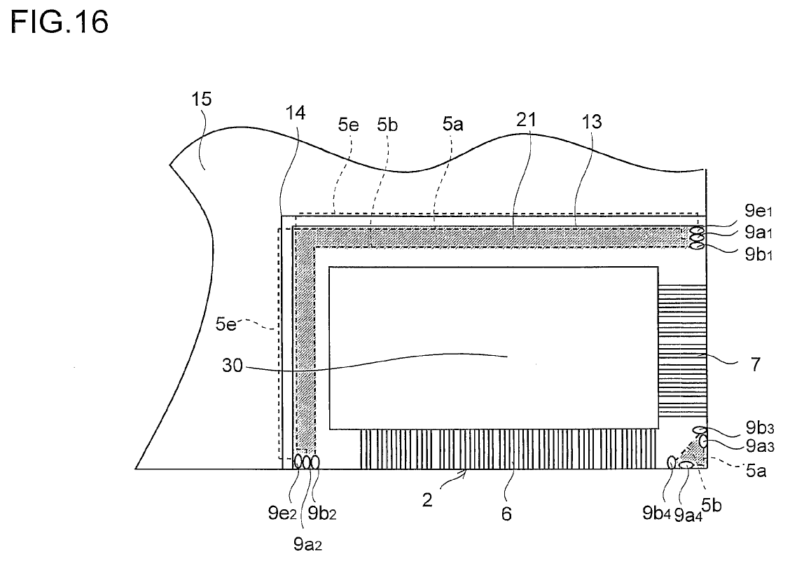

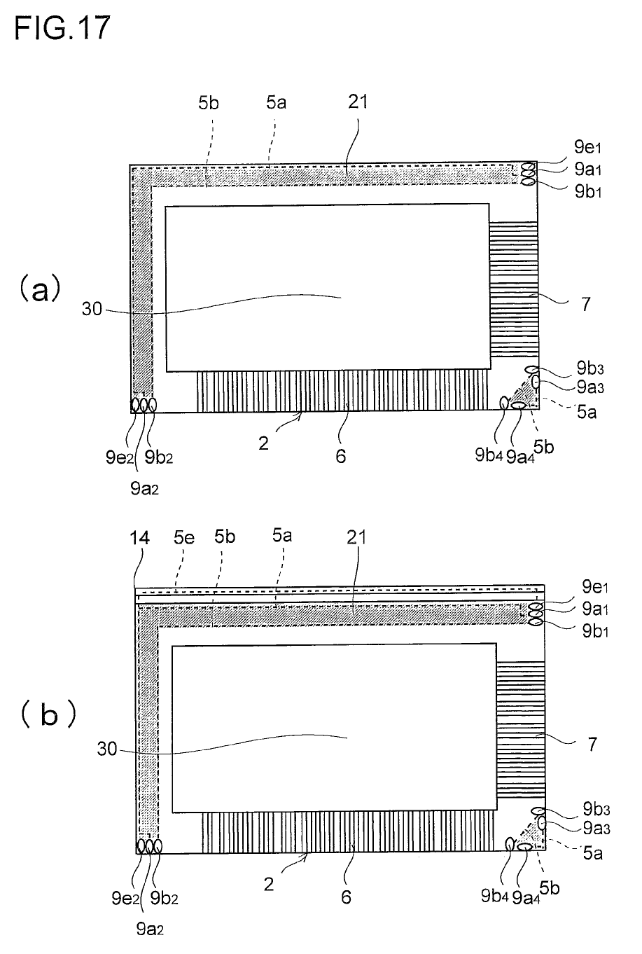

### BRIEF DESCRIPTION OF DRAWINGS

[FIG. 1] A perspective view showing a liquid crystal display panel of a first embodiment;

[FIG. 2] An exploded perspective view showing the liquid crystal display panel of the first embodiment;

[FIG. 3] A plan view showing the liquid crystal display panel of the first embodiment;

[FIG. 4] A front view showing the surface configuration of a pixel substrate in the liquid crystal display panel of the first embodiment;

[FIG. 5] A front view showing the surface configuration of the pixel substrate in the liquid crystal display panel of the first embodiment;

[FIG. 6] A front view showing the surface configuration of the pixel substrate in the liquid crystal display panel of the first embodiment;

[FIG. 7] A front view showing the surface configuration of the pixel substrate in the liquid crystal display panel of the first embodiment;

[FIG. 8] A front view showing the surface configuration of the pixel substrate in the liquid crystal display panel of the first embodiment;

[FIG. 9] A front view showing the surface configuration of the pixel substrate in the liquid crystal display panel of the first embodiment;

[FIG. 10] An exploded perspective view showing a liquid crystal display panel of a second embodiment;

[FIG. 11] (a) A plan view showing the surface configuration of a pixel substrate of the liquid crystal display panel of the second embodiment;
(b) A plan view showing the surface configuration of a counter substrate of the liquid crystal display panel of the second embodiment;

[FIG. 12] (a) A plan view showing the surface configuration of the pixel substrate of the liquid crystal display panel of the second embodiment;
(b) A plan view showing the surface configuration of the counter substrate of the liquid crystal display panel of the second embodiment;

[FIG. 13] (a) A plan view showing the surface configuration of the pixel substrate of the liquid crystal display panel of the second embodiment;
(b) A plan view showing the surface configuration of the counter substrate of the liquid crystal display panel of the second embodiment;

[FIG. 14] (a) A plan view showing the surface configuration of the pixel substrate of the liquid crystal display panel of the second embodiment;
(b) A plan view showing the surface configuration of the counter substrate of the liquid crystal display panel of the second embodiment;

[FIG. 15] (a) A plan view showing the surface configuration of the pixel substrate of the liquid crystal display panel of the second embodiment;
(b) A plan view showing the surface configuration of the counter substrate of the liquid crystal display panel of the second embodiment;

[FIG. 16] A front view showing the surface configuration of a pixel substrate of a liquid crystal display panel of a third embodiment before division;

[FIG. 17] (a) A plan view showing the surface configuration of the pixel substrate of the liquid crystal display panel of the third embodiment obtained by division performed along division lines; and
(b) A plan view showing the surface configuration of the pixel substrate of the liquid crystal display panel of the third embodiment obtained by division performed outside of a shape acceptance line.

### LIST OF REFERENCE SYMBOLS

1 liquid crystal display panel

2 pixel substrate

21 acceptance area

3 liquid crystal layer

4 counter substrate

41 acceptance area

5a first inspecting conductor

5b second inspecting conductor

5c third inspecting conductor

5d fourth inspecting conductor

5e fifth inspecting conductor

6 scanning line

7 data line

9a-9e inspecting pads

12c, d transfer electrodes

13 division line

14 outer edge of acceptance area

15 insulating substrate

30 active area

### BEST MODE FOR CARRYING OUT THE INVENTION

Hereinafter, embodiments of the present invention will be described with reference to the drawings.

### First Embodiment

A liquid crystal display panel 1 of this embodiment has been invented as one having a configuration suitable for the inspecting method according to the present invention. FIG. 1 is a perspective view showing the liquid crystal display panel 1 of this embodiment, FIG. 2 is an exploded perspective view showing the liquid crystal display panel 1, and FIG. 3 is a front view showing the liquid crystal display panel 1. The liquid crystal display panel 1 is configured such that a pixel substrate 2 and a counter substrate 4 face each other and liquid crystal 4 is sealed between the two substrates.

Here, the pixel substrate has a display area 30 in which a plurality of scanning lines 6 and a plurality of data lines 7 are provided on a transparent insulating substrate so as to intersect each other. Corresponding to each of intersections between the plurality of scanning lines 6 and the plurality of data lines 7, there are formed a pixel electrode and a TFT serving as a switching device for driving the pixel electrode. In performing display on the liquid crystal display panel, a potential is selectively written to each of the pixel electrodes from the scanning lines 6 and the data lines 7, liquid crystal between a pixel electrode and a counter electrode is modulated by a voltage difference between the pixel electrode and the counter electrode, and thereby a display pattern is formed in the display area 30. The scanning lines 6 and the data lines 7 are connected to electrode terminals (not illustrated), an area of the counter substrate facing the electrode terminals is separated from the display area of the liquid crystal display panel, and the electrode terminals are exposed to the outside and electrically connected to driving ICs (not shown).

In the manufacturing process of the liquid crystal display panel, when an insulating substrate is divided, a flaw such as a crack or a chip may occur in part of the edge of the pixel substrate 2. In the descriptions below, a flaw that leads to a large break in the insulating substrate will be referred to as a crack, and one that does not lead to a large break in the insulating substrate will be referred to as a chip.

On the transparent insulating substrate of the pixel substrate 2, a first inspecting conductor 5a is laid along its outer edge, and a second inspecting conductor 5b is laid on the inner periphery side of the first inspecting conductor 5a. The first and second inspecting conductors 5a and 5b are provided for detecting a crack or a chip.

In a case in which a crack or a chip has occurred in the edge of the pixel substrate 2, the first inspecting conductor 5a is easily cut. This cut of the first inspecting conductor 5a makes it possible to detect occurrence of a crack or a chip by applying a voltage to an inspecting pad 9a connected to each end of the first inspecting conductor 5a to perform resistance inspection.

Here, since a crack occurring in the edge of the pixel substrate 2, even if it is a minute one, may lead to a large break in the insulating substrate in the future, a liquid crystal display panel in which a crack has occurred needs to be judged as defective. On the other hand, in a case in which a minute chip has occurred in the edge of the pixel substrate 2, if the chip is not likely to lead to a large break in the insulating substrate in the future and is not so large as to degrade the quality of the liquid crystal display panel, the liquid crystal display panel can be judged as non-defective.

As a basis for judging whether or not the chip is acceptable, an acceptance area 21 (the shaded area in the figure) formed in the pixel substrate 2 inward from the edge of the pixel substrate 2. A liquid crystal display panel having a chip so large as to extend out of the acceptance area 21 has occurred is judged as defective. Here, in the pixel substrate 2 of this embodiment, a second inspecting conductor 5b is provided along the inner edge of the acceptance area 21, and like the first inspecting conductor 5a, the second inspecting conductor 5b is also easily cut by a crack or a chip occurring in the insulating substrate.

Thus, in a case in which the second inspecting conductor 5b is found to be cut as a result of resistance inspection performed by applying a voltage to a second inspecting pad 9b connected to each end of the second inspecting conductor 5b, it can be assumed that a crack or a chip has occurred which is so large as to extend off the acceptance area 21 in the liquid crystal display panel 1.

Thus, in a ease in which, as a result of resistance inspection, both the first and second inspection conductors 5a and 5b are found to be cut, it can be judged that a crack or a chip that is too large to be accepted has occurred in the liquid crystal panel 1, and the liquid crystal display panel 1 can be judged as defective, without performing visual inspection. On the other hand, in a case in which neither the first inspection conductor 5a nor the second inspection conductor 5b is found to be cut, it can be assumed that there is no crack in the pixel substrate 2, and the liquid crystal display panel 1 can be judged as non-defective, without performing visual inspection.

In a case in which either one of the first and second inspecting conductors 5a and 5b is found to be cut, since it is impossible to determine whether the panel is defective or non-defective only from the results of the resistance inspection, a judgment needs to be made after visual inspection is performed to find out the cause of the cut.

Incidentally, in FIGS. 1 to 3, although the first and second inspecting conductors 5a and 5b are laid on two side of the pixel substrate 2 along the edge thereof, this is not meant as a limitation, and it is possible to change the arrangement of the first and second inspecting conductors 5a and 5b according to the arrangement of the scanning and data lines 6 and 7, electrode terminals (not shown) connected to them, and driving ICs (not shown).

Also, preferably, the first and second inspecting conductors 5a and 5b are as thin as possible. The first and second inspecting conductors 5a and 5b can be formed by being patterned in a predetermined shape together with the first and second inspecting pads 9a and 9b when conductors such as the data lines 7 and the scanning lines 6 are formed on the pixel substrate 2.

Next, a method for inspecting liquid crystal display panels according to this embodiment will be described by using a specific example. The method for inspecting liquid crystal display panels according to the present invention is a combination of a resistance inspection process and an optical inspection process by visual inspection. The resistance inspection process is performed with respect to the liquid crystal display panel 1 after it is cut off by using a cutting member such as a wheel cutter, and a voltage is applied to each of the inspecting pads 9a and 9b formed on the surface to thereby inspect the first and second inspecting conductors 5a and 5b for a cut. Incidentally, the method for inspecting liquid crystal display panels described below can be performed with respect to liquid crystal display panels not only after but also before the filling liquid crystal.

FIG. 4 is a front view of the surface structure of the pixel substrate 2 in the liquid crystal display panel 1, showing that a chip C1 has occurred in the edge of the pixel substrate 2 and part of the first inspecting conductor 5a is cut. The chip C1 is not so large as to extend out of the acceptance area 21, and thus the second inspecting conductor 5b is not cut.

In the liquid crystal display panel 1 shown in FIG. 4, as a result of a resistance inspection process performed by applying a voltage to the inspecting pad 9a connected to each end of the first inspecting conductor 5a and to the inspecting pad 9b connected to each end of the second inspecting conductor 5b, the first inspecting conductor 5a is found to be cut, while the second inspecting conductor 5b is not found to be cut.

In a case in which, as described above, a cut is found only in the first inspecting conductor 5a out of the first and second inspecting conductors 5a and 5b, it can be assumed that a crack that will lead to a large break in the future or a minute chip of an acceptable size has occurred in the edge of the pixel substrate 2. However, since it is impossible to judge only by the resistance inspection whether it is a crack or a chip that has occurred, it is necessary for optical inspection such as visual inspection to be performed to find out the cause of the cut after the resistance inspection to judge whether or not the liquid crystal display panel 1 is non-defective. Here, in a case in which, as a result of the visual inspection, it is found that the chip C1 has occurred in the edge of the pixel substrate 2 to have an acceptable size and that the shape of the chip C1 is not one that will later lead to a large break of the substrate, the liquid crystal display panel is judged as non-defective.

FIG. 5 is a front view of the surface structure of the pixel substrate 2 in the liquid crystal display panel 1, showing that a chip C2 has occurred in the edge of the pixel substrate 2 and that part of the first and second inspecting conductor 5a and 5b is cut. The chip C2 is not one that is likely to lead to a large break in the future, but it is so large that it extends out of the acceptance area 21.

In the liquid crystal display panel 1 shown in FIG. 5, as a result of a resistance inspection process performed by applying a voltage to the inspecting pad 9a connected to each end of the first inspecting conductor 5a and to the inspecting pad 9b connected to each end of the second inspecting conductor 5b, it can be judged that both the first and second inspecting conductors 5a and 5b are cut. Based on this, it can be assumed that a crack or a chip has occurred in the edge of the pixel substrate 2 to extend out of the acceptance area 21.

In this way, in the case in which both the first and second inspecting conductors 5a and 5b are found to be cut, the liquid crystal display panel 1 is judged as non-defective, without performing visual inspection.

FIG. 6 is a front view of the surface structure of the pixel substrate 2 in the liquid crystal display panel 1, showing that a crack C3 that will lead to a large break in the future has occurred in the edge of the pixel substrate 2, and that part of the first inspecting conductor 5a is cut. The crack C3 is not so large as to extend out of the acceptance area 21, and thus the second inspecting conductor 5b is not cut.

In the liquid crystal display panel 1 shown in FIG. 6, as a result of a resistance inspection process performed by applying a voltage to the inspecting pad 9a connected to each end of the first inspecting conductor 5a and to the inspecting pad 9b connected to each end of the second inspecting conductor 5b, the first inspecting conductor 5a is found to be cut, while the second inspecting conductor 5b is not found to be cut. Based on this, it can be assumed that the cut of the first inspecting conductor 5a has been caused by a crack that will lead to a large break in the future or by an acceptably minute chip.

Thus, in a case in which one of the first and second inspecting conductors 5a and 5b is found to be cut, it is necessary for visual inspection to be performed after the resistance inspection to find out the cause of the cut to judge whether or not the liquid crystal display panel 1 is non-defective. Here, in a case in which, as a result of the visual inspection, the crack C3 is found to be a crack that will lead to a large break of the substrate in the future, the liquid crystal display panel is judged as defective.

FIG. 7 is a front view of the surface structure of the pixel substrate 2 in the liquid crystal display panel 1, showing that part of the second inspecting conductor 5b of the pixel substrate 2 is cut by a pattern failure P1. The first inspecting conductor 5a is not cut.

In the liquid crystal display panel 1 shown in FIG. 7, as a result of a resistance inspection process performed by applying a voltage to the inspecting pad 9a connected to each end of the first inspecting conductor 5a and to the inspecting pad 9b connected to each end of the second inspecting conductor 5b, a cut is found to have occurred only in the second inspecting conductor 5b, and not in the first inspecting conductor 5a. In this case, since the first inspecting conductor 5a is not cut, it can be assumed that it is not a fracture, a crack, or a chip that has caused the cut of the second inspecting conductor 5b.

Thus, in a case in which one of the first and second inspecting conductors 5a and 5b is found to be cut, it is necessary for visual inspection to be performed after the resistance inspection to find out the cause of the cut to judge whether or not the liquid crystal display panel 1 is non-defective. As a result of the visual inspection, if the pattern failure P1 can be identified as the cause of the cut, since this pattern failure does not degrade the quality of the liquid crystal display panel, the liquid crystal display panel 1 is judged as non-defective.

FIG. 8 is a front view of the surface structure of the pixel substrate 2 in the liquid crystal display panel 1, showing that part of the first inspecting conductor 5a of the pixel substrate 2 is cut by a pattern failure P2. The second inspecting conductor 5b is not cut.

In the liquid crystal display panel 1 shown in FIG. 8, as a result of a resistance inspection process performed by applying a voltage to the inspecting pad 9a connected to each end of the first inspecting conductor 5a and to the inspecting pad 9b connected to each end of the second inspecting conductor 5b, a cut is found to have occurred only in the first inspecting conductor 5a, not in the second inspecting conductor 5b.

Thus, in a case in which one of the first and second inspecting conductors 5a and 5b is found to be cut, it is necessary for visual inspection to be performed after the resistance inspection to find out the cause of the cut to judge whether or not the liquid crystal display panel 1 is non-defective. As a result of the visual inspection, if the pattern failure P2 can be identified as the cause of the cut, since this pattern failure does not degrade the quality of a liquid crystal display panel, the liquid crystal display panel 1 is judged as non-defective.

FIG. 9 is a front view of the surface structure of the pixel substrate 2 in the liquid crystal display panel 1, showing that no crack or no chip has occurred in the pixel substrate 2.

In the liquid crystal display panel 1 shown in FIG. 9, as a result of a resistance inspection process performed by applying a voltage to the inspecting pad 9a connected to each end of the first inspecting conductor 5a and to the inspecting pad 9b connected to each end of the second inspecting conductor 5b, neither the first inspecting conductor 5a nor the second inspecting conductor 5b is found to be cut. Based on this result, it can be assumed that no crack or no chip has occurred in the edge of the pixel substrate 2.

In a case in which, as described above, neither the first inspecting conductor 5a nor the second inspecting conductor 5b is found to be cut, the liquid crystal display panel 1 is judged as non-defective, without performing visual inspection.

Thus, in a case in which both the first and second inspecting conductors are found to be cut, the liquid crystal display panel is judged as defective, without performing visual inspection. In a case in which neither the first inspecting conductor nor the second inspecting conductor is found to be cut, the liquid crystal display panel is judged as non-defective, without performing visual inspection. In a case in which either the first or second inspecting conductor is found to be cut, visual inspection is performed to find out the cause of the cut to evaluate the liquid crystal display panel.

Thus, by sorting liquid crystal display panels into defective and non-defective ones first by resistance inspection, and subsequently performing optical inspection only with respect to those that cannot be evaluated by the resistance inspection alone, liquid crystal display panels can be inspected with improved efficiency.

### Second Embodiment

Next, a liquid crystal display panel 1 according to a second embodiment of the present invention will be described with reference to the drawings. Parts common to those in the above described first embodiment are identified by the same reference numbers, and descriptions thereof will be omitted. FIG. 10 is an exploded perspective view showing the liquid crystal display panel 1 of this embodiment. The liquid crystal display panel 1 of this embodiment has a configuration similar to the configuration of the liquid crystal display panel 1 of the first embodiment, that is, it is an active-matrix liquid crystal display panel configured such that a counter substrate 4 is disposed to face a pixel substrate 2 and liquid crystal 3 is sealed between the substrates 2 and 4.

FIG. 11(a) is a plan view showing the surface structure of the pixel substrate 2 of the liquid crystal display panel 1 of this embodiment. The pixel substrate 2 has a display area 30 in which a plurality of scanning lines 6 and a plurality of data lines 7 are provided to intersect each other on a transparent insulating substrate. Here, corresponding to each of intersections between the plurality of scanning lines 6 and the plurality of data lines 7, there are formed a pixel electrode and a TFT serving as a switching device for driving the pixel electrode. In performing display on the liquid crystal display panel, a potential is selectively written to each of the pixel electrodes from the scanning lines 6 and the data lines 7, liquid crystal between a pixel electrode and a counter electrode is modulated by a voltage difference between the pixel electrode and the counter electrode, and thereby a display pattern is formed in the display area 30. The scanning lines 6 and the data lines 7 are connected to electrode terminals (not shown), an area of the counter substrate facing the electrode terminals is separated from the display area of the liquid crystal display panel, and the electrode terminals are exposed to the outside and electrically connected to driving ICs (not shown).

A first inspecting conductor 5a is laid along the edge of the transparent insulating substrate of the pixel substrate 2, and a second inspecting conductor 5b is laid inside the first inspecting conductor 5a. The first and second inspecting conductors 5a and 5b are provided for detecting a crack or a chip occurring in part of the edge of the pixel substrate 2 when the insulating substrate is divided into individual pixel substrates.

In a case in which a crack or a chip has occurred in the edge of the pixel substrate 2, the first inspecting conductor 5a is easily cut. This cut of the first inspecting conductor 5a makes it possible to detect occurrence of a crack or a chip by applying a voltage to an inspecting pad 9a connected to each end of the first inspecting conductor 5a to perform resistance inspection.

Here, since a crack occurring in the edge of the pixel substrate 2, even if it is a minute one, may lead to a large break of the insulating substrate in the future, a liquid crystal display panel in which a crack has occurred needs to be judged as defective. On the other hand, in a case in which a minute chip has occurred in the edge of the pixel substrate 2, if the chip is not likely to lead to a large break in the insulating substrate in the future and is so minute that will not degrade the quality of the liquid crystal display panel, the pixel substrate 2 can be judged as non-defective.

As a basis for judging whether or not the chip is acceptable, an acceptance area 21 (the shaded area in the figure) is provided over a predetermined area inward from the edge of the pixel substrate 2. A liquid crystal display panel having a chip so large as to extend out of the acceptance area 21 is judged as defective. Here, in the pixel substrate 2 of this embodiment, a second inspecting conductor 5b is provided along the inner edge of the acceptance area 21, and like the first inspecting conductor 5a, the second inspecting conductor 5b is also easily cut by a crack or a chip occurring in the insulating substrate.

Thus, in a case in which the second inspecting conductor 5b is found to be cut as a result of resistance inspection performed by applying a voltage to the second inspecting pad 9b connected to each end of the second inspecting conductor 5b, it can be assumed that a crack or a chip that extends out of the acceptance area 21 has occurred in the pixel substrate 2.

Thus, in a case in which, as a result of resistance inspection of the first and second inspecting conductors 5a and 5b, both the first and second inspecting conductors 5a and 5b are found to be cut, it can be judged that a crack or a chip that is too large to be accepted has occurred in the pixel substrate 2, and the pixel substrate 2 can be judged as defective, without performing visual inspection. On the other hand, in a case in which neither the first inspecting conductor 5a nor the second inspecting conductor 5b is found to be cut, it can be assumed that there is no crack in the pixel substrate 2, and the pixel substrate 2 can be judged as non-defective, without performing visual inspection.

Thus, in a case in which one of the first and second inspecting conductors 5a and 5b is found to be cut, since whether the pixel substrate 2 is defective or non-defective cannot be judged by the resistance inspection alone, it needs to be judged after visual inspection is performed and the cause of the cut is found out.

FIG. 11(b) is a plan view showing the surface structure of the counter substrate 4 of the liquid crystal display panel 1 of this embodiment. A counter electrode (not shown) is formed on the surface of the counter substrate 4, a third inspecting conductor 5c is laid along the edge of the counter substrate 4, and a fourth inspecting conductor 5d is laid inside the third inspecting conductor 5c. In the same manner that the first and second inspecting conductors 5a and 5b are provided for detecting a crack or a chip in the pixel substrate 2, the third and fourth inspecting conductors 5c and 5d are provided for detecting a crack or a chip in the counter substrate 4.

In the same manner that the acceptance area 21 is provided in the pixel substrate 2, an acceptance area 41 (the shaded area in the figure) is provided as a basis for judging whether or not a chip that has occurred in the counter substrate 4 is acceptable, and the fourth inspecting conductor 5d is laid along the inner edge of the acceptance area 41.

The third and fourth inspecting conductors 5c and 5d are easily cut in a case in which a crack or a chip has occurred in the counter substrate 4, and thus a crack or a chip occurred in the counter substrate 4 can be detected by applying a voltage to an inspecting pad 9c connected to each end of the third inspecting conductor 5c and to an inspecting pad 9d connected to each end of the fourth inspecting conductor 5d.

Thus, in a case in which, as a result of resistance inspection of the third and fourth inspecting conductors 5c and 5d, both the third and fourth inspecting conductors 5c and 5d are found to be cut, it can be judged that a crack or a chip that is too large to be accepted has occurred in the counter substrate 4, and the counter substrate 4 can be judged as defective, without performing visual inspection. In a case in which neither the third inspecting conductor 5c nor the fourth inspecting conductor 5d is found to be cut, it can be assumed that there is no crack in the counter substrate 4, and the counter substrate 4 can be judged as non-defective, without performing visual inspection.

In a case in which one of the third and fourth inspecting conductors 5c and 5d is found to be cut, since whether the counter substrate 4 is defective or non-defective cannot be judged by the resistance inspection alone, it needs to be judged after visual inspection is performed and the cause of the cut is found out.

Thus, first, resistance inspection is performed with respect to the first, second, third, and fourth inspecting conductors 5a, 5b, 5c, and 5d to inspect for a cut to thereby judge whether the pixel and counter substrates 2 and 4 are defective or non-defective, and then, based on the result, visual inspection is performed to judge whether the liquid crystal display panel 1 is defective or non-defective. This makes it possible to prevent defective products from being shipped, to reduce manufacturing cost, and to provide highly reliable liquid crystal display panels.

Incidentally, as shown in FIG. 10, the third and fourth inspecting conductors 5c and 5d are formed on a surface of the counter substrate 4 that faces the pixel substrate 2. Each end of the third inspecting conductor 5c is connected to the inspecting pad 9c via a transfer electrode 12c and each end of the fourth inspecting conductor 5d is connected to the inspecting pad 9d via a transfer electrode 12d. The inspecting pads 9c and 9d are formed on the pixel substrate 2, and the transfer electrodes 12c and 12d are laid between the pixel and counter substrates 2 and 4 when the substrates are attached to each other.

Thus, the inspecting pads 9a, 9b, 9c, and 9d are arranged on a part of the pixel substrate 2 that is exposed to the outside, and this allows resistance inspection to be performed with improved efficiency.

The third and fourth inspecting conductors 5c and 5d can be formed by patterning a transparent electrode formed of an ITO or the like in a predetermined shape on one of the insulating substrates.

Next, a description will be given of an inspecting method of liquid crystal display panels according to this embodiment. The inspecting method of liquid crystal display panels according to the present invention is a combination of a resistance inspection process and an optical inspection process by visual inspection. The resistance inspection process is performed with respect to the liquid crystal display panel 1 after it is cut off by using a cutting member such as a wheel cutter, and a voltage is applied to each of the inspecting pads 9a, 9b, 9c, and 9d formed on the surface of the pixel substrate 2 to thereby inspect the first, second, third and fourth inspecting conductors 5a, 5b, 5c, and 5d for a cut. The method for inspecting the liquid crystal display panel 1 will be described by using a specific example.

FIG. 12(a) is a front view showing the surface structure of the pixel substrate 2 in the liquid crystal display panel 1, and FIG. 12(b) is a front view showing the surface structure of the counter substrate 4 in the liquid crystal display panel 1. There is no chip, crack, or the like in the pixel substrate 2, but a chip C4 has occurred in the edge of the counter substrate 4, and part of the third inspecting conductor 5c is cut. The chip C4 is not so large as to extend out of the acceptance area 41, and thus the fourth inspecting conductor 5d is not cut.

With the liquid crystal display panel 1 shown in FIG. 12, as a result of the resistance inspection process performed by applying a voltage to each of the inspecting pads 9a, 9b, 9c, and 9d connected to each end of the first, second, third, and fourth inspecting conductors 5a, 5b, 5c, and 5d, respectively, the third inspecting conductor 5c is found to be cut, while the other inspecting conductors are not found to be cut. Based on this, it can be judged that the pixel substrate 2 has no crack or the like and thus is non-defective, and it can also be assumed that the cut of the third inspecting conductor 5c has been caused because a crack that will lead to a large break in the future or a minute chip of an acceptable size has occurred in the edge of the counter substrate 4.

Thus, in a case in which one of the third and fourth inspecting conductors 5c and 5d is found to be cut, it is necessary for visual inspection to be performed after the resistance inspection to find out the cause of the cut to judge whether or not the liquid crystal display panel 1 is non-defective. Here, in a case in which, as a result of the visual inspection, the chip C4 is found to be a chip having an acceptable size and a shape that will not lead to a large break of the substrate, the liquid crystal display panel is judged as non-defective.

FIG. 13(a) is a front view showing the surface structure of the pixel substrate 2 in the liquid crystal display panel 1, and FIG. 13(b) is a front view showing the surface structure of the counter substrate 4 in the liquid crystal display panel 1. There is no chip, crack, or the like in the pixel substrate 2, but a chip C5 has occurred in the edge of the counter substrate 4, and part of the fourth inspecting conductor 5d is cut. The chip CS will not lead to a large break in the future, but it is so large as to extend out of the acceptance area 41.

With the liquid crystal display panel 1 shown in FIG. 13, as a result of the resistance inspection process performed by applying a voltage to each of the inspecting pads 9a, 9b, 9c, and 9d connected to the two ends of the first, second, third, and fourth inspecting conductors 5a, 5b, 5c, and 5d, respectively, the third and fourth inspecting conductors 5c and 5d are found to be cut. Based on this, it can be judged that the pixel substrate 2 has no crack or the like and thus is non-defective, and it can be assumed that a crack or a chip extending out of the acceptance area 41 has occurred in the edge of the counter substrate 4.

In this way, in a case in which both the third and fourth inspecting conductors 5c and 5d are found to be cut, the liquid crystal display panel 1 is judged as defective, without performing visual inspection.

FIG. 14(a) is a front view showing the surface structure of the pixel substrate 2 in the liquid crystal display panel 1, and FIG. 14(b) is a front view showing the surface structure of the counter substrate 4 in the liquid crystal display panel 1. There is no chip, crack, or the like in the pixel substrate 2, but a crack 5 has occurred in the edge of the counter substrate 4, and part of the third inspecting conductor 5c is cut. The crack C5 is not so large as to extend out of the acceptance area 41, and thus the fourth inspecting conductor 5d is not cut.

With the liquid crystal display panel 1 shown in FIG. 14, as a result of the resistance inspection process performed by applying a voltage to the inspecting pads 9a, 9b, 9c, and 9d connected to the two ends of the first, second, third, and fourth inspecting conductors 5a, 5b, 5c, and 5d, the third inspecting conductor 5c is found to be cut while the other inspecting conductors are not found to be cut. Based on this, it can be judged that the pixel substrate 2 has no crack or the like and thus is non-defective, and it can be assumed that the cut of the third inspecting conductor 5c has been caused by a crack that will lead to a large break or by a minute chip of an acceptable size.

Thus, in a case in which one of the third and fourth inspecting conductors 5c and 5d is found to be cut, it is necessary for visual inspection to be performed to find out the cause of the cut after the resistance inspection before judging that the liquid crystal display panel 1 is non-defective. Here, in a case in which, as a result of the visual inspection, the crack C6 is found to be a crack that will lead to a large break of the substrate, the liquid crystal display panel is judged as defective.

FIG. 15(a) is a front view showing the surface structure of the pixel substrate 2 in the liquid crystal display panel 1, and FIG. 15(b) is a front view showing the surface structure of the counter substrate 4 in the liquid crystal display panel 1. A crack C7 that will lead to a large break in the future has occurred in the edge of the pixel substrate 2 and part of the first inspecting conductor 5a is cut. The crack C7 is not so large as to extend out of the acceptance area 21, and thus the second inspecting conductor 5b is not cut.

A chip C8 has occurred in the edge of the counter substrate 4, and part of the third inspecting conductor 5c is cut. The chip C8 is not so large as to extend out of the acceptance area 41, and thus the fourth inspecting conductor 5d is not cut.

With the liquid crystal display panel 1 shown in FIG. 15, as a result of the resistance inspection process performed by applying a voltage to each of the inspecting pads 9a, 9b, 9c, and 9d connected to the two ends of the first, second, third, and fourth inspecting conductors 5a, 5b, 5c, and 5d, respectively, the first and third inspecting conductors 5a and 5c are found to be cut while the other inspecting conductors arc not found to be cut. Based on this, it can be assumed that the cut of the first inspecting conductor 5a in the pixel substrate 2 has been caused by a crack that will lead to a large break in the future or by a minute chip of an acceptable size, and it can be assumed that the cut of the third inspecting conductor 5c in the counter substrate 4 has been caused by a crack that will lead to a large break in the future or by a minute chip of an acceptable size.

Thus, in a case in which one of the first and second inspecting conductors 5a and 5b in the pixel substrate 2 is found to be cut, or in a case in which one of the third and fourth inspecting conductors 5c and 5d in the counter substrate 4 is found to be cut, it is necessary for visual inspection to be performed to find out the cause of the cut after the resistance inspection before judging that the liquid crystal display panel 1 is non-defective. Here, even in a case in which, as a result of the visual inspection, the chip C8 occurring in the edge of the counter substrate 4 is found to be a chip having an acceptable size and a shape that will not lead to a large break of the substrate, if the crack C7 in the pixel substrate 2 is found to be a crack that will lead to a large break of the substrate in the future, the liquid crystal display panel is judged as defective.

Thus, in a case in which both the first and second inspecting conductors are found to be cut or in which both the third and fourth inspecting conductors are found to be cut, the liquid crystal display panel is judged as defective, without performing visual inspection. In a case in which none of the first to fourth inspecting conductors is found to be cut, the liquid crystal display panel is judged as non-defective, without performing visual inspection. In a case in which the first or second inspecting conductor is found to be cut, visual inspection is performed with respect to the pixel substrate 2 alone to find out the cause of the cut, and then the liquid crystal display panel is evaluated. In a case in which the third or fourth inspecting conductor is found to be cut, visual inspection is performed with respect to the counter substrate 4 alone to find out the cause of the cut, and then the liquid crystal display panel is evaluated.

Thus, liquid crystal display panels can be inspected more efficiently by first finding liquid crystal display panels 1 that can be judged as defective or non-defective by using resistance inspection, and then performing visual inspection with respect to liquid crystal display panels that cannot be judged as non-defective by the resistance inspection alone.

### Third Embodiment

Next, a description will be given of a liquid crystal display panel 1 of a third embodiment of the present invention. Parts common to those in the above described first and second embodiments are identified by the same reference numbers, and descriptions thereof will be omitted. The liquid crystal display panel 1 of this embodiment also has a configuration similar to the configuration of the liquid crystal display panel 1 of the first embodiment, that is, it is an active-matrix liquid crystal display panel configured such that a counter substrate 4 is disposed so as to face a pixel substrate 2 and liquid crystal 3 is sealed between the substrates 2 and 4.

FIG. 16 is a front view of the surface structure of the pixel substrate 2 in the liquid crystal display panel 1. The liquid crystal display panel of the present invention is manufactured by dividing an insulating substrate along a division line 13, and the division line 13 becomes an edge of the liquid crystal display panel 1. On an insulating substrate 15, a display area 30 is formed in which a plurality of scanning lines 6 and a plurality of data lines 7 are provided to intersect each other. In the display area 30, at each one of intersections between the plurality of scanning lines 6 and the plurality of data lines 7, there are formed a pixel electrode and a switching device for driving the pixel electrode. In performing display on the liquid crystal display panel, potentials are selectively written to the pixel electrodes from the scanning lines 6 and the data lines 7, liquid crystal between a pixel electrode and a counter electrode 4 is modulated by a voltage difference between the pixel electrode and the counter electrode 4, and thereby a display pattern is formed in the display area 30. The scanning lines 6 and the data lines 7 are connected to electrode terminals (not illustrated), an area of the counter substrate facing the electrode terminals is separated from the display area of the liquid crystal display pane, and the electrode terminals are exposed to the outside and electrically connected to driving ICs (not shown).

Here, in the manufacturing process of the liquid crystal display panel 1, the insulating substrate 15 is typically divided after it is scribed along the division line 13 with a cutting member such as a wheel cutter (hereinafter, “wheel cutter”). In a case in which a division position at which the insulating substrate 15 is divided is formed deviating so much from the division line 13 that it is out of a predetermined area, the liquid crystal display panel is judged as deflective. As a basis for judgment of whether or not the division position is acceptable, a predetermined acceptance area is provided outside the division line 13. That is, unless a scribe position is formed out of an outer edge 14 of the acceptance area, the liquid crystal display panel is judged as non-defective.

In the pixel substrate-side insulating substrate 15 of the liquid crystal display panel 1 of this embodiment, a fifth inspecting conductor 5e is laid along the outer edge 14 of the acceptance area, and the fifth inspecting conductor 5e is connected to a first inspecting conductor near an intersection at which division lines 13 in a longitudinal direction and in a lateral direction intersect each other. The fifth inspecting conductor 5e is connected to inspecting pads 9e₁ and 9e₂ provided inside the division line 13 on the pixel substrate 2.

As a result, in a case in which the insulating substrate 15 is divided along the predetermined division line 13 inside the outer edge 14 of the acceptance area, the fifth inspecting conductor 5e is cut together with the insulating substrate 15. On the other hand, when the insulating substrate 15 is divided at a position outside the outer edge 14 of the acceptance area, the fifth inspecting conductor 5e is not cut.

Here, since the dividing process of the liquid crystal display panel includes the scribing along the division lines 13 of longitudinal and lateral directions, deviation of division-position occurs independently in each of the division lines 13 of the longitudinal and lateral directions.

FIG. 17 is a plan view showing the surface structure of the pixel substrate 2 in the liquid crystal display panel 1 of this embodiment after division. In FIG. 17(a), the liquid crystal display panel 1 is cut off along the division lines 13 in the longitudinal and lateral directions, and in FIG. 17(b), the liquid crystal display panel 1 is cut off along the division line in the longitudinal direction, but in the lateral direction, it is cut off along a line outside the outer edge 14 of the acceptance area.

As is clear from comparison between FIG. 16 and FIG. 17(a), in the pixel substrate 2 cut off along the division line 13, the fifth inspecting conductor 5e is cut when the insulating substrate 15 is divided at positions where it is connected to the fifth inspecting pads 9e₁ and 9e₂ and at a position where it is connected to the first inspecting conductor 5a.

Thus, a cut is detected as a result of resistance inspection performed by applying a voltage to the fifth inspecting pad 9e₁ and to a first inspecting pad 9a₁ that are connected to inspecting conductors laid along the same direction to inspect the fifth inspecting conductor 5e for a cut. This shows that the insulating substrate 15 has been divided within the acceptance area in the lateral direction. In the same fashion, a cut is detected in the fifth inspecting conductor 5e as a result of resistance inspection performed by applying a voltage to the fifth inspecting pad 9e₂ and to a first inspecting pad 9a₂, and this shows that the insulating substrate 15 has been divided within the acceptance area in the longitudinal direction. Thus, by performing resistance inspection, the liquid crystal display panel 1 shown in FIG. 17(a) can be judged as non-defective with respect to which division positions are fanned within the acceptance area.

On the other hand, as is clear from comparison between FIG. 16 and FIG. 17(b), the pixel substrate 2 shown in FIG. 17(b) is cut off along the division line 13 in the longitudinal direction, and the fifth inspecting conductor 5e is cut when the insulating substrate 15 is divided at a position where it is connected to the fifth inspecting pad 9e₂ and at a position where it is connected to the first inspecting conductor 5a. Thus, a cut is detected as a result of resistance inspection performed by applying a voltage to the fifth inspecting pad 9e₂ and to a first inspecting pad 9a₂ connected to inspecting conductors laid along the same direction to inspect the fifth inspecting conductor 5e for a cut. Thus, the results of the resistance inspection show that the insulating substrate 15 is divided within the acceptance area in the longitudinal direction.

The pixel substrate 2 is cut off in the lateral direction not along the division line 13 but out of the outer edge 14 of the acceptance area, and thus the insulating substrate 15 is divided with the fifth inspecting conductor 5e remaining connected to the fifth inspecting pad 9e₁ and to the first inspecting conductor 5a. Thus, no cut is detected as a result of resistance inspection performed by applying a voltage to the fifth inspecting pad 9e₁ and to the first inspecting pad 9a₁ to inspect the fifth inspecting conductor 5e for a cut. Thus, it can be assumed that the insulating substrate 15 is cut out of the outer edge 14 of the acceptance area in the lateral direction, and the liquid crystal display panel can be judged as defective.

Thus, by performing resistance inspection by applying a voltage to the first and fifth inspecting pads 9a and 9e to inspect the fifth inspecting conductor 5e for a cut, it can be judged whether or not the insulating substrate 15 is divided out of the outer edge 14 of the acceptance area, and the liquid crystal display panel can be evaluated.

The first inspecting conductor 5a is laid along the division line 13 that is to be the edge of the pixel substrate 2, and a second inspecting conductor 5b is laid inside the first inspecting conductor 5a. Like those shown in the above-described first embodiment, the first and second inspecting conductors 5a and 5b are provided for the purpose of detecting a crack or a chip that may occur on part of the edge of the pixel substrate 2 along the division line 13 in the manufacturing process of the liquid crystal display panel.

The second inspecting conductor 5b is laid along an edge of the acceptance area 21 (the shaded area in the figure) that is provided as a basis for judging whether or not a chip occurring in the edge of the pixel substrate 2 is acceptable. Thus, in a case in which a chip has occurred to extend out of the acceptance area 21, the second inspecting conductor 5b is easily cut, and thus, based on a result of resistance inspection performed by applying a voltage to the inspecting pad 9b connected each end of the second inspecting conductor 5b, it can be assumed that a crack or a chip extending out of the acceptance area 21 has occurred in the pixel substrate 2.

As described above, in the inspecting method for inspecting the liquid crystal display panel 1 according to this embodiment, resistance inspection is first performed by applying a voltage to the first inspecting pad 9a and to the fifth inspecting pad 9e each corresponding to a division-line direction, and in a case in which the fifth inspecting conductor 5e is found not to be cut at least in one division-line direction, the division position is judged to be unacceptably deviated, and the liquid crystal display panel 1 is judges as defective. On the other hand, in a case in which the fifth inspecting conductor 5e is found to be cut in all the division-line directions, deviation of the division position is judged to be within the acceptance area, and subsequently, resistance inspection is performed with respect to the first and second inspecting conductors 5a and 5b, in the same manner as in the liquid crystal display panel-inspecting method of the first embodiment. As a result, in a case in which both the first inspecting conductor 5a and the second inspecting conductor 5b are found to be cut, the pixel substrate 2 can be judged as defective, without performing visual inspection, and in a case in which neither the first inspecting conductor 5a nor the second inspecting conductor 5b is found to be cut, it can be assumed that there is no crack, chip, or break occurring in the pixel substrate 2, and the pixel substrate 2 can be judged as non-defective, without performing visual inspection.

In a case in which one of the first and second inspecting conductors 5a and 5b is found to be cut, since whether the pixel substrate 2 is defective or non-defective cannot be judged by the resistance inspection alone, it needs to be judged after visual inspection is performed to find out the cause of the cut.

Incidentally, although the counter substrate 4 in the liquid crystal display panel 1 of this embodiment is not provided with third and fourth inspecting conductors 5c and 5d, it is possible to provide third and fourth inspecting conductors 5c and 5d on the counter substrate 4 as shown in the second embodiment so as to add to the inspecting process an inspecting process for detecting a crack, a chip, or a break in the counter substrate 4.

Whether or not the insulating substrate of the counter substrate 4 is cut off outside the outer edge of an acceptance area can be judged based on a result of resistance inspection performed by applying a voltage to an inspecting pad in the same manner as performed with respect to the above-described fifth inspecting conductor 5e with the following configuration; that is, a predetermined acceptance area is provided outside a division line in the counter substrate 4, an inspecting conductor is provided along the outer edge of the acceptance area, the inspecting conductor is drawn out to the inside of the division line on the counter substrate to be connected to inspecting pads on the pixel substrate 2 via a transfer electrode laid between the pixel and counter substrates 2 and 4 when they are attached to each other. The inspecting method here can be performed following the same procedure as described above.

It is preferable that the fifth inspecting conductor 5e, the first inspecting conductor 5a, and the second inspecting conductor 5b be as thin as possible, and they can be formed by patterning in a predetermined shape together with the inspecting pads 9a, 9b, and 9e when conductors such as the data lines 7 and the scanning lines 6 on the pixel substrate 2 are formed.

Incidentally, although, with the liquid crystal display panel 1 of this embodiment, the insulating substrate 15 is cut off along the division line 13 laid along two sides, this is not meant to limit the present invention, and the technical scope of this invention also includes cases in which the insulating substrate 15 is cut off along a division line 13 laid along one side, three sides, or four sides. It is also possible to detect a chip or a break occurring in a corner of the liquid crystal display panel 1 by using inspecting pads 9a₃, 9a₄, 9b₃, and 9b₄.

The present invention is, however, by no means limited to the above-described embodiments, allowing various modifications within the technical spirit and scope of the present invention, and embodiments obtained by appropriately combining technical means disclosed in different embodiments with each other are also included in the technical scope of the present invention. For example, a liquid crystal display panel can be regarded as one according to the present invention if it has at least one of the first, second, third, fourth, and fifth inspecting conductors 5a, 5b, 5c, 5d, and 5e provided either on the pixel substrate 2 or on the counter substrate 4 described in the above embodiments.

### INDUSTRIAL APPLICABILITY

The present invention is applicable to a liquid crystal display devices, and can be used in liquid crystal displays using such liquid crystal display devices.

1. A liquid crystal display panel, comprising:
a pixel substrate in which a plurality of pixel electrodes and switching devices for switching the pixel electrodes are provided on an insulating substrate;
a counter substrate in which a counter electrode is provided on an insulating substrate; and
a liquid crystal layer held between the pixel substrate and the counter substrate,
wherein
a first inspecting conductor is laid along an edge of the pixel substrate, and
wherein
resistance inspection is performed with respect to the first inspecting conductor by using a first inspecting pad electrically connected to each end of the first inspecting conductor to thereby detect a crack or a chip occurring in the edge of the pixel substrate.

2. The liquid crystal display panel of claim 1,
wherein
a second inspecting conductor is laid along an inner edge of an acceptance area provided to have a predetermined width inward from the edge of the pixel substrate, and
wherein
resistance inspection is performed with respect to the second inspecting conductor by using a second inspecting pad electrically connected to each end of the second inspecting conductor to there by detect a crack or a chip occurring in the edge of the pixel substrate.

3. The liquid crystal display panel of claim 1,
wherein
a third inspecting conductor is laid along an edge of the counter substrate, and
wherein
resistance inspection is performed with respect to the third inspecting conductor by using a third inspecting pad electrically connected to each end of the third inspecting conductor to thereby detect a crack or a chip occurring in the edge of the counter substrate.

4. The liquid crystal display panel of claim 3, wherein the third inspecting pad is provided on the pixel substrate.

5. The liquid crystal display panel of claim 3,
wherein
a fourth inspecting conductor is laid along an inner edge of an acceptance area provided to have a predetermined width inward from the edge of the counter substrate, and
wherein
resistance inspection is performed with respect to the fourth inspecting conductor by using a fourth inspecting pad electrically connected to each end of the fourth inspecting conductor to thereby detect a crack or a chip occurring in the edge of the counter substrate.

6. The liquid crystal display panel of claim 5, wherein the fourth inspecting pad is provided on the pixel substrate.

7. The liquid crystal display panel of claim 1 obtained by dividing the insulating substrate along a division line,
wherein
a fifth inspecting conductor is laid along an outer edge of an acceptance area provided to have a predetermined width outward from the division line in the insulating substrate of the pixel substrate,
wherein
the fifth inspecting conductor is connected to the first inspecting conductor near a division-line intersection,
wherein
a fifth inspecting pad electrically connected to each end of the fifth inspecting conductor is provided inside the division line, and
wherein
resistance inspection is performed with respect to resistance between the fifth and first inspecting conductors by using the fifth and first inspecting pads to thereby detect division performed deviating outward from the division line.

8. An inspecting method for inspecting the liquid crystal display panel of claim 1, comprising:
a resistance inspection process in which a voltage is applied to at least one of the first and second inspecting conductors; and
an optical inspection process by visual inspection,
wherein,
in the resistance inspection process, the liquid crystal display panel is evaluated in terms of defection level to judge whether or not the optical inspection process is to be performed.

9. The liquid crystal display panel of claim 2, wherein
a third inspecting conductor is laid along an edge of the counter substrate, and
wherein
resistance inspection is performed with respect to the third inspecting conductor by using a third inspecting pad electrically connected to each end of the third inspecting conductor to thereby detect a crack or a chip occurring in the edge of the counter substrate.

10. The liquid crystal display panel of claim 9, wherein the third inspecting pad is provided on the pixel substrate.

11. The liquid crystal display panel of claim 9,
wherein
a fourth inspecting conductor is laid along an inner edge of an acceptance area provided to have a predetermined width inward from the edge of the counter substrate, and
wherein
resistance inspection is performed with respect to the fourth inspecting conductor by using a fourth inspecting pad electrically connected to each end of the fourth inspecting conductor to thereby detect a crack or a chip occurring in the edge of the counter substrate.

12. The liquid crystal display panel of claim 11, wherein the fourth inspecting pad is provided on the pixel substrate.

13. The liquid crystal display panel of claim 2 obtained by dividing the insulating substrate along a division line,
wherein
a fifth inspecting conductor is laid along an outer edge of an acceptance area provided to have a predetermined width outward from the division line in the insulating substrate of the pixel substrate,
wherein
the fifth inspecting conductor is connected to the first inspecting conductor near a division-line intersection,
wherein
a fifth inspecting pad electrically connected to each end of the fifth inspecting conductor is provided inside the division line, and
wherein
resistance inspection is performed with respect to resistance between the fifth and first inspecting conductors by using the fifth and first inspecting pads to thereby detect division performed deviating outward from the division line.

14. An inspecting method for inspecting the liquid crystal display panel of claim 2, comprising:
a resistance inspection process in which a voltage is applied to at least one of the first and second inspecting conductors; and
an optical inspection process by visual inspection,
wherein,
in the resistance inspection process, the liquid crystal display panel is evaluated in terms of defection level to judge whether or not the optical inspection process is to be performed.
